(19) United States
(12) Patent Application Publication
(10) Pub. No.: US 2014/0131911 A1
(43) Pub. Date: May 15, 2014

(54) Cartridge Reactor for Production of Materials via the Chemical Vapor Deposition Process

(71) Applicant: Kagan Ceran, Carlsbad, CA (US)

(72) Inventor: Kagan Ceran, Carlsbad, CA (US)

(73) Assignee: GREENLY GROUP FOR SOLAR TECHNOLOGIES, LTD., Road Town, Tortola (VG)

(21) Appl. No.: 14/130,669

(22) PCT Filed: Jul. 1, 2012
(86) PCT No.: PCT/US2012/045177

§ 371 Date: Jan. 2, 2014

Related U.S. Application Data
(63) Continuation-in-part of application No. 12/597,151, filed on Oct. 22, 2009, now Pat. No. 8,449,940.
(60) Provisional application No. 61/504,145, filed on Jul. 1, 2011.
(60) Provisional application No. 61/504,148, filed on Jul. 1, 2011.
(60) Provisional application No. 60/913,997, filed on Apr. 25, 2007.

(51) Int. Cl. B81C 1/00

(52) U.S. Cl. CPC B81C 1/00349
USPC 264/129

(57) ABSTRACT

The present invention overcomes the limitations of Siemens reactors by providing for the deposition reaction to occur inside of a sealed crucible rather than inside of the overall cavity of a water-cooled reactor. The crucible itself is positioned inside of a cartridge reactor, which can have heat shields between crucible and the reactor walls to significantly reduce radiant energy losses. Additionally, the ratio of deposition surface area to cavity volume in the crucible is much higher than that in the ratio of rod deposition surface area to overall cavity volume in Siemens reactors, which results in a much higher contact percentage of gas molecules with the deposition surfaces. This in turn results in a much higher actual conversion ratio of material in the gas to material on the deposition surfaces.

The present patent application incorporates by reference in its entirety U.S. patent application Ser. No. 12/597,151 (the “'151 patent application”), Deposition of high-purity silicon via high-surface-area gas-solid or gas-liquid interfaces and recovery via liquid phase, filed Oct. 22, 2009. This application also incorporates by reference in its entirety the co-pending application entitled: DEPOSITION CARTRIDGE FOR PRODUCTION OF MATERIALS VIA THE CHEMICAL VAPOR DEPOSITION PROCESS filed concurrently herewith (whose application Ser. No. ______ will be added once known). The present patent application also claims benefit of U.S. provisional patent application No. 61/504,148 (the “'148 provisional patent application”), Deposition cartridge for production of high-purity amorphous and crystalline silicon and other materials, filed Jul. 1, 2011, and provisional patent application No. 61/504,145 (the “'145 provisional patent application”), filed Jul. 1, 2011, Cartridge reactor for production of high-purity amorphous and crystalline silicon and other materials, which are both hereby incorporated herein in their entireties. In the '151 patent application, the term “deposition plates” is defined as the surfaces upon which the silicon is deposited, but for the purposes of enhanced clarity when describing actual physical components in this patent application, a “deposition surface” is defined as a surface upon which materials are deposited and a “deposition plate” is defined as an actual physical flat plate (an object with significantly larger surface areas on its sides relative to its edges) upon which materials are deposited, preferably on both sides as well as one or more edges. Thus the sides and edges of a deposition plate are deposition surfaces. The term “deposition cartridge” is defined as the combination of distribution rods and a solid deposition plate or as simply a meander patterned deposition plate, either of which can incorporate an insulative layer or spacer. The term “Siemens reactor” is defined as a deposition reactor that has originally been designed to utilize seed rods.

### BACKGROUND

The '151 patent application describes the limitations of Siemens reactors as including:
1. The low average surface area of the polysilicon rods which results in a low volumetric deposition rate and hence low Siemens reactor productivity (as measured by the mass of polysilicon produced over a given period of time, typically metric tons per year)
2. The low ratio of surface area to volume of the polysilicon rods, which results in high energy consumption in order to maintain the surface temperature required to achieve deposition for the extended period of time required to achieve a meaningful deposition volume.
3. The labor-intensive and contamination-prone nature of the rod harvesting process

The invention described in the '151 patent application overcomes these limitations by providing high-surface-area electrically heated deposition plates. Silicon is deposited at a high volumetric rate onto these plates through the CVD process and then recovered by additional heating of the plates. The additional heating causes a very thin layer of the deposited polysilicon at the plate interfaces to liquefy and the solid crust of deposited polysilicon can be pulled away from the plates either mechanically or by gravity. Using large-sized plates in a Siemens reactor increases the productivity of the reactor relative to using conventional seed rods whereas using smaller-sized plates reduces the energy consumption of the reactor while maintaining the same productivity relative to using seed rods. However, further limitations of Siemens reactors remain, including but not limited to:
1. High radiant energy loss from the rods to the reactor walls which must be cooled in order to prevent deposition of polysilicon onto the walls in addition to the rods
2. Low contact percentage of deposition gas molecules with the deposition surface area due to the low ratio of deposition surface area to reactor overall cavity volume. The low actual conversion ratio of silicon in the gas to silicon on the rods, relative to the theoretical conversion ratio, which is governed by reaction equilibria, is the result of low contact percentage.

### SUMMARY

The present invention overcomes the limitations of Siemens reactors described above by providing for the deposition reaction to occur inside of a sealed crucible rather than inside of the overall cavity of a water-cooled reactor. Deposition onto the inner walls of the reactor is undesirable as it results in loss of the material to be produced, whereas deposition onto the inner walls of the crucible is actually desirable as it increases the volumetric deposition rate due to the addition of deposition surface area. The crucible itself is positioned inside of a cartridge reactor, which can have heat shields between the crucible and the reactor walls to significantly reduce radiant energy losses. Typically up to 60-70% of the energy used by Siemens reactors is lost to their unshielded water-cooled walls.

Additionally, the ratio of deposition surface area to cavity volume in the crucible is much higher than that in the ratio of rod deposition surface area to overall cavity volume in Siemens reactors, which results in a much higher contact percentage of gas molecules with the deposition surfaces. This in turn results in a much higher actual conversion ratio of material in the gas to material on the deposition surfaces.

### BRIEF DESCRIPTION OF DRAWINGS

FIG. 1 shows an elevation section of one preferred embodiment of the main components of the cartridge reactor

FIG. 2 shows plan sections of one preferred embodiment of the main components of the cartridge reactor

FIG. 3 shows a perspective of one preferred embodiment of deposition cartridges for the cartridge reactor

FIG. 4 shows an elevation section of one preferred embodiment of the cartridge reactor with the bottom assembly lowered and the crucible being loaded

FIG. 5 shows an elevation section of one preferred embodiment of the cartridge reactor with the bottom assembly raised and the reactor pressurized with inert gas

FIG. 6 shows an elevation section of one preferred embodiment of the cartridge reactor with the crucible raised and the deposition cartridges preheated

FIG. 7 shows an elevation section of one preferred embodiment of the cartridge reactor during the deposition sequence

FIG. 8 shows an elevation section of one preferred embodiment of the cartridge reactor during directional solidification with inert gas in the reactor

FIG. 9 shows an elevation section of one preferred embodiment of the cartridge reactor during cool down and air purge

FIG. 10 shows an elevation section of one preferred embodiment of the cartridge reactor with the bottom assembly lowered and the crucible being unloaded

FIG. 11 shows a side elevation section of one preferred embodiment of the reactor top assembly

FIG. 12 shows a front elevation section of one preferred embodiment of the reactor top assembly

FIG. 13 shows a plan section (looking up) of one preferred embodiment of the reactor top assembly

FIG. 14 shows a side elevation section of one preferred embodiment of the crucible during deposition showing gas flow patterns

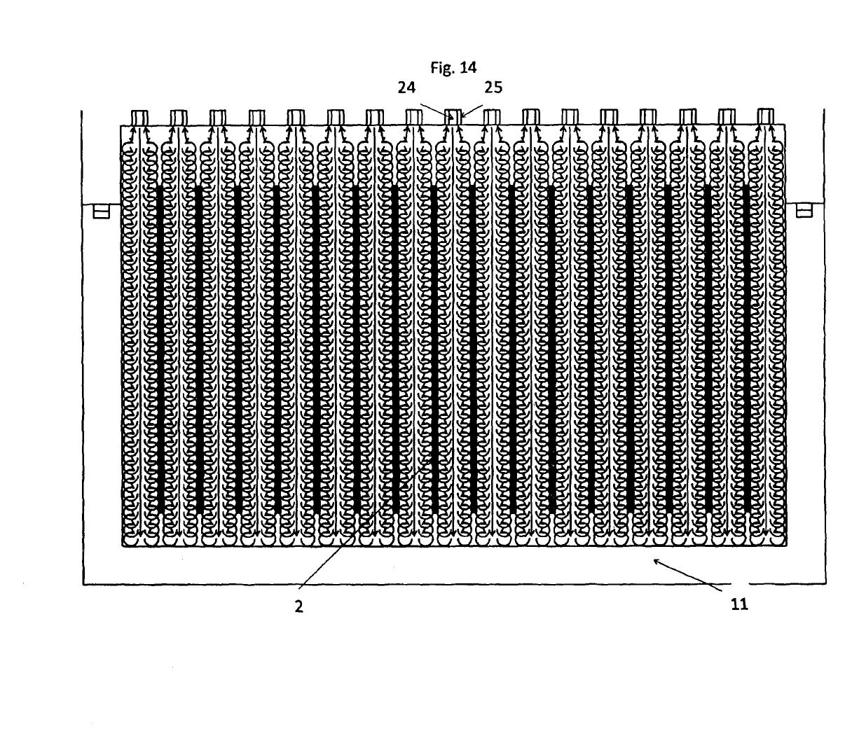

FIG. 15 shows a plan section of one preferred embodiment of the crucible after deposition showing material crusts

### DESCRIPTION

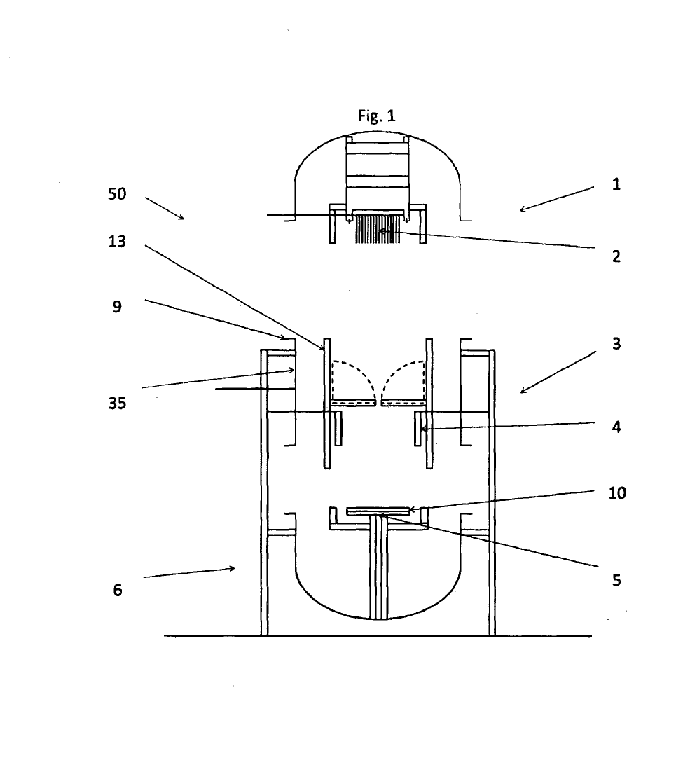

The main components of one preferred embodiment of the cartridge reactor 50 for the production of materials via the CVD process are shown in FIG. 1. In this embodiment, the reactor top assembly 1 functions to support the deposition cartridges 2 (which are described in the '148 and '145 patent applications and in the DEPOSITION CARTRIDGE FOR PRODUCTION OF MATERIALS VIA THE CHEMICAL VAPOR DEPOSITION PROCESS application filed concurrently herewith), distribute the deposition gas mix over the deposition surfaces of the deposition cartridges 2, remove the vent gas, and to affect heat exchange between the vent gas and the deposition gas mix. The array of deposition cartridges 2 preferably has a square plan section if the desired final product is multicrystalline material or preferably a circular plan section if the desired final product is monocrystalline material. The reactor top assembly 1 is attached to the reactor middle assembly 3 by the reactor flanges 9 which incorporate an airtight seal. The reactor middle assembly 3 houses a crystallization heater 4. The reactor bottom assembly 6, which can be raised to and lowered from the reactor middle assembly 3, houses a crucible pedestal 5 which is equipped with a bottom cooler 10 for cooling the crucible during directional solidification and which is capable of vertical travel. All assemblies of the reactor incorporate heat shields to minimize radiant energy losses.

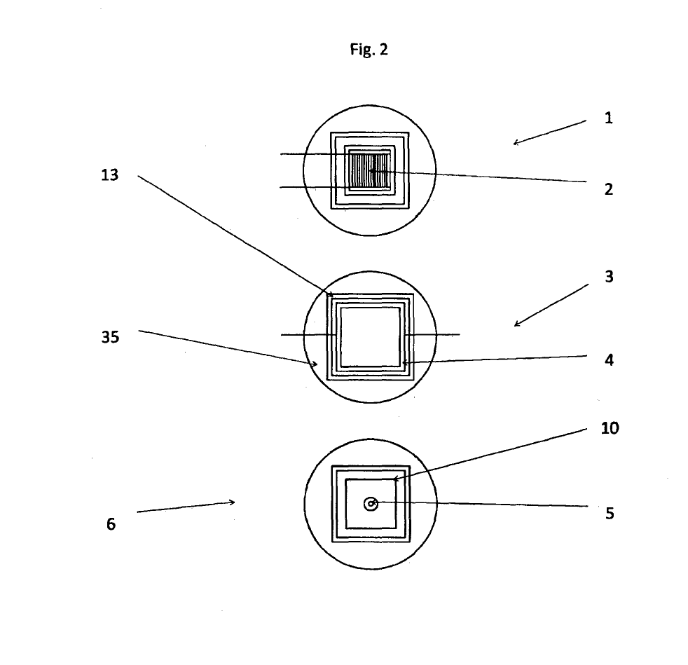

As shown in FIG. 2, the reactor walls 35 of the reactor top assembly 1, reactor middle assembly 3, and reactor bottom assembly 6 are preferably circular in plan section, and they are also preferably water cooled. The plan sections of the heat shields 13, array of deposition cartridges 2, crystallization heater 4, and bottom cooler 10 are preferably square if multicrystalline material is desired and preferably circular if monocrystalline material is desired.

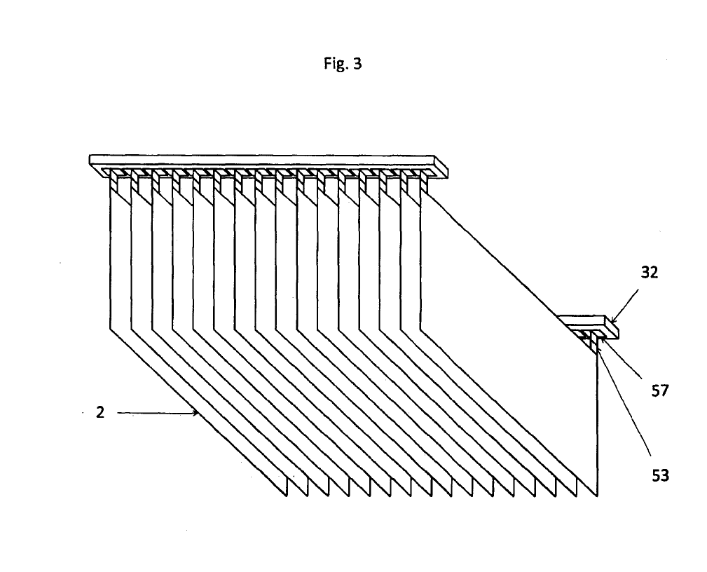

FIG. 3 shows a perspective of one preferred embodiment of the array of deposition cartridges 2 that are fitted to the reactor top assembly. The deposition cartridges 2 are connected, by their electrode tabs 53, to the distribution bar 32 by electrode brackets 57. There are 16 deposition cartridges 2 which are spaced approximately 5 cm apart and which have a height of approximately 42 cm and a length of approximately 75 cm. Assuming a deposition crust thickness of approximately 2 cm on the deposition cartridges 2 and on the inner walls of the crucible, the array of deposition cartridges 2 in this preferred embodiment is designed to fit inside of an 85 cm by 85 cm crucible typically used for the crystallization of deposition materials, including but not limited to polysilicon.

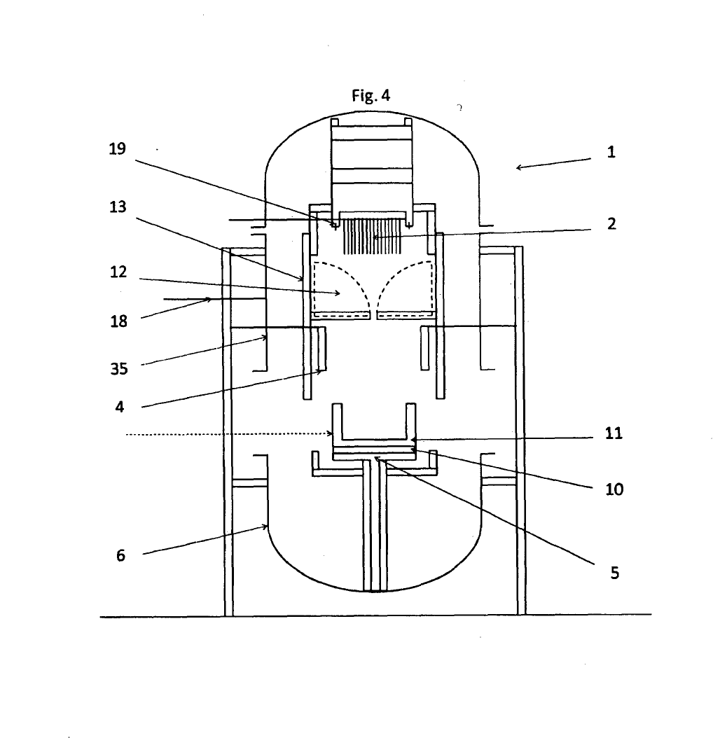

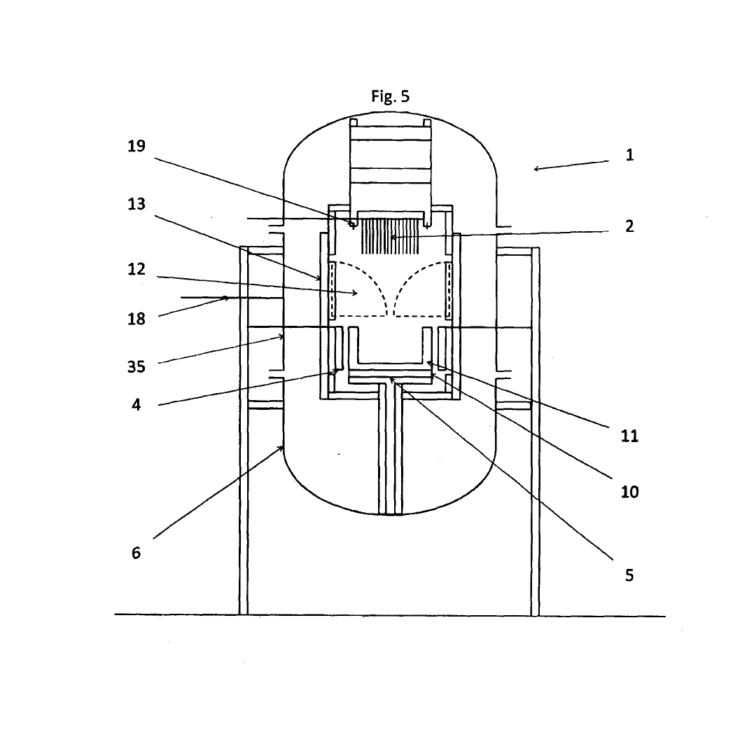

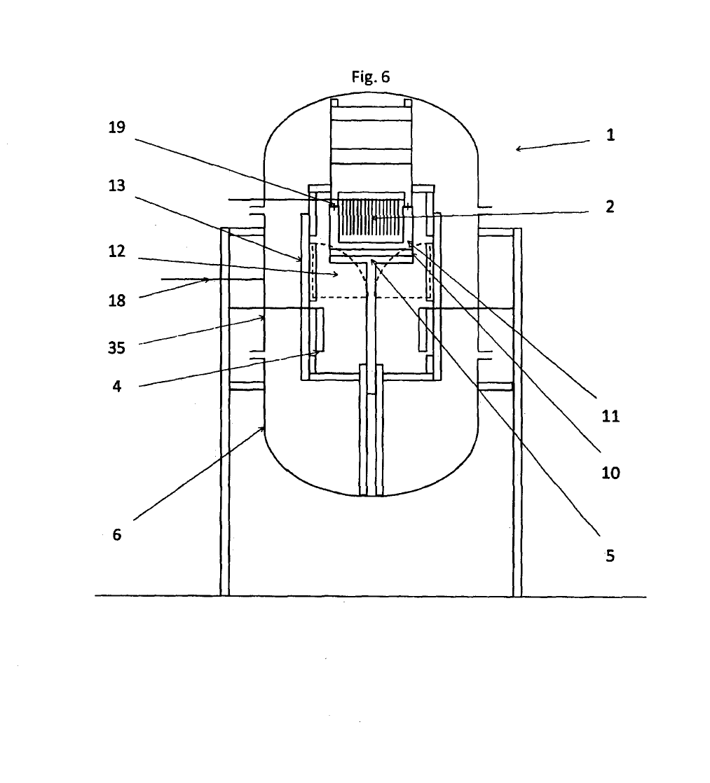

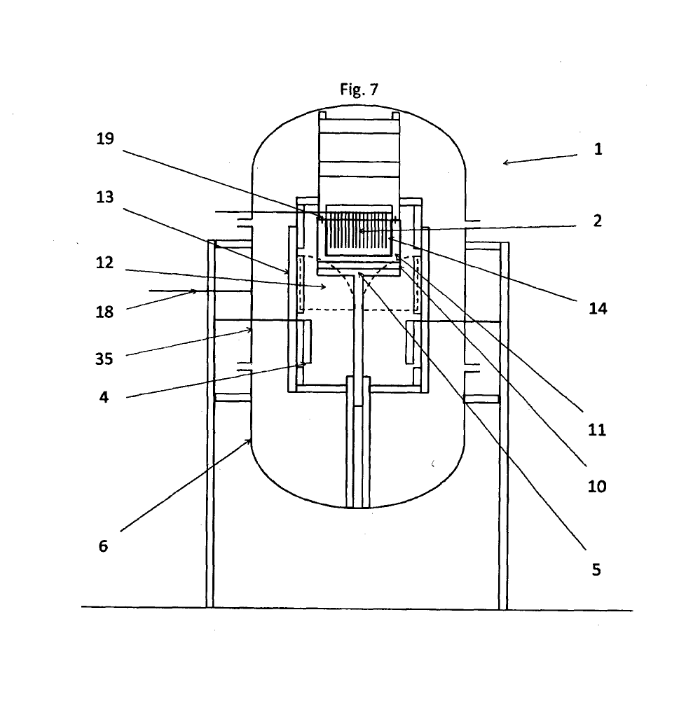

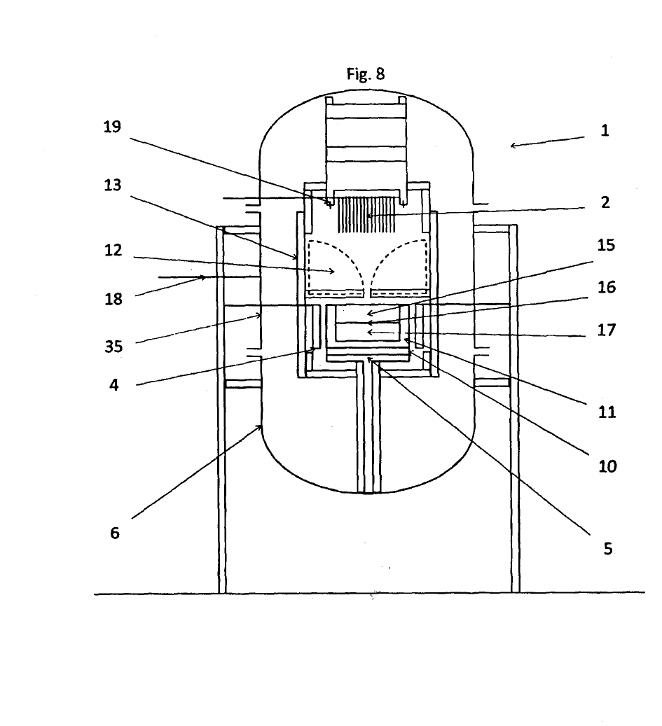

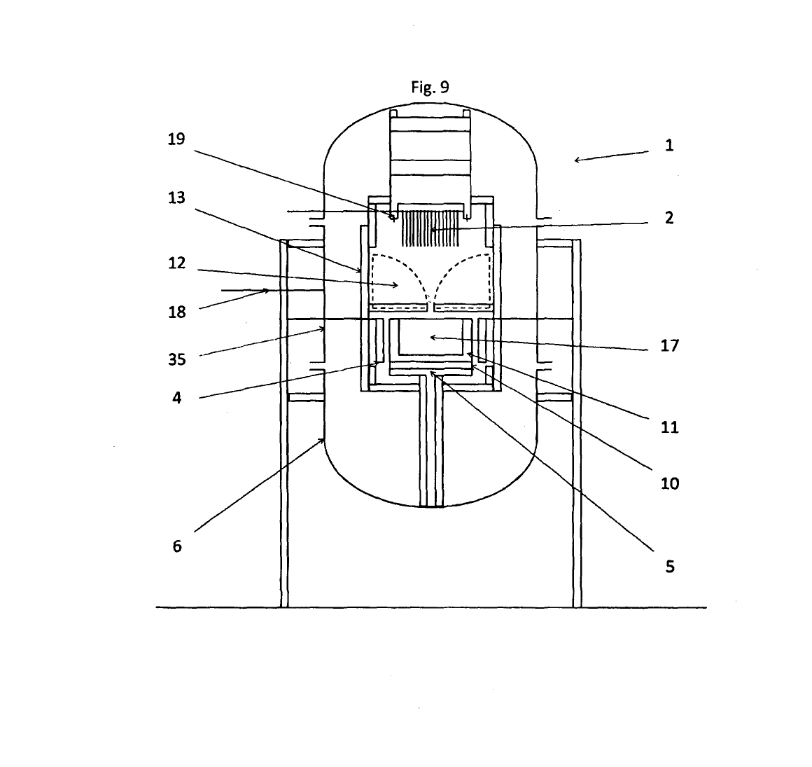

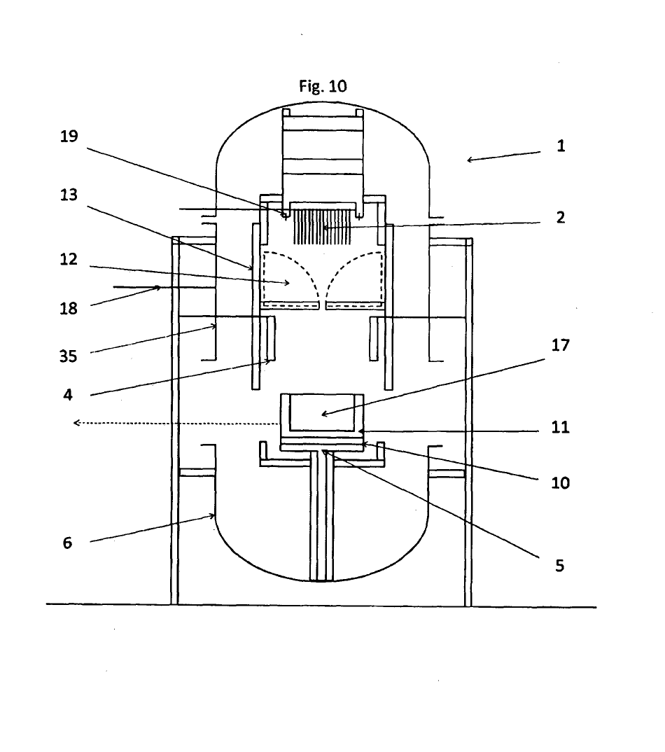

This preferred embodiment of the cartridge reactor 50 is operated in the following preferred seven steps:
1. A crucible-loading step is shown in FIG. 4. Preferably, the reactor bottom assembly 6 is lowered and the crucible 11, which is preferably quartz, is precisely positioned onto the crucible pedestal 5.
2. An inert gas purge step is shown in FIG. 5. Preferably, the reactor bottom assembly 6 is raised and the airtight reactor flanges 6 of the reactor bottom assembly and of the reactor middle assembly 3 are sealed. The reactor cavity is purged with an inert gas, preferably nitrogen, using the reactor gas inlets 18 and the reactor top assembly 1 gas inlets and outlets. Preferably, the cartridge reactor 50 is also brought up to operating pressure, (preferably in the range of 6 bar).
3. A preheating step is shown in FIG. 6. Preferably, the crucible pedestal 5 is raised so that the top edges of the crucible 11 press against the gas seal 19 and form an airtight seal. Preferably, the deposition cartridges 2 are then electrically preheated to the optimal deposition temperature, which is preferably in the range of 850° C. to 1,150° C. when the deposition material is polysilicon. Heat shields 13 in the cartridge reactor 50 minimize radiant energy losses and minimize the cooling duty of the water-cooled reactor walls 35.
4. A deposition sequence step is shown in FIG. 7. Preferably, the deposition gas mix, which is preferably trichlorosilane and hydrogen or monosilane when the deposition material is polysilicon, is pumped into the crucible 11 from gas inlets in the reactor top assembly 1 while inert gas, which is preferably nitrogen, is maintained in the rest of the reactor cavity outside of the crucible. Preferably, for safety, the inert gas is at a slightly higher pressure than the deposition gas so that in the unlikely event of a leak in the gas seal 19, inert gas will leak into the crucible 11 rather than flammable deposition gas mix leaking outside of the crucible 11. Alternatively in this preferred embodiment, if there is a leak in the reactor flanges 9, inert gas will leak outside of the cartridge reactor 50 rather than flammable deposition gas mix leaking outside of the cartridge reactor 50, which is an additional safety improvement over Siemens reactors. The gas seal 19 is preferably chosen to withstand relatively high temperatures, for which there are preferred seal materials, such as carbon-based materials, but the gas seal preferably experiences a relatively small pressure differential. Preferably, the deposition gas mix that is pumped into the crucible 11 comes into contact with the heated deposition surfaces of the deposition cartridges 2, undergoes the deposition reaction, converts into the vent gas and is removed through gas outlets in the reactor top assembly 1. In this preferred embodiment, this process continues until a material crust 14 has accumulated on the deposition surfaces such that most of the void volume inside the crucible 11 is filled. At this point, both the inside and outside of the crucible 11 are purged with a suitable inert gas, preferably argon, and preferably a vacuum is drawn both inside and outside of the crucible 11. Then, the deposition surfaces are further heated to or above the melting point of the material, causing a thin layer of the material at the deposition surfaces of the deposition cartridges 2 to liquefy and the material crust to detach from the deposition cartridges 2.
5. A crystallization step is shown in FIG. 8. Preferably, the crucible pedestal 5 carrying the crucible 11 and the material crust 14 is lowered into the reactor middle assembly 3, and the material crust 14 is further heated by the crystallization heater 4 until it becomes liquid material 15. Preferably, the heat shields 13 can incorporate a reflective layer to minimize radiant energy losses and an insulating layer outside of the reflective layer to minimize convective and conductive energy losses. In this preferred embodiment, directional solidification is achieved through one or more means including activation of the bottom cooler 10, control of the crystallization heater 4, and/or movement of the crucible pedestal 5 away from the crystallization heater 4. During this crystallization step, the rotating heat shield 12 is closed to provide insulation over the top of the crucible 11 in order to minimize energy losses. The solidification front 16 moves upward through the liquid material 15, forming a crystalline material ingot 17 behind it. In another preferred embodiment of the above crystallization step, the material crust 14 can be fully melted by the deposition cartridges 2 while the crucible 11 is still in the fully raised position. The crucible 11 can then be lowered in a controlled manner while the deposition cartridges 2 continue to heat the liquid silicon and the bottom cooler 10 is activated to initiate directional solidification. This preferred embodiment has the potential to accelerate the crystallization process as well as produce higher quality crystalline silicon by keeping the solidification front 16 more planar. Both preferred embodiments described above result in the production of multicrystalline material and a square plan section geometry for the array of deposition cartridges 2, the crucible 11, and the bottom cooler 10 is preferred. However, in another preferred embodiment, if this plan section geometry is circular and a rotating puller rod is introduced from the reactor top assembly 1 into the liquid material 15, a monocrystalline ingot can also be produced, by the Czochralski crystallization process. Finally, in another preferred embodiment, this entire crystallization step can be omitted and the cartridge reactor 50 can be used to produce just amorphous material in crucibles for further processing elsewhere.
6. A cool down and air purge step is shown in FIG. 9, where the vacuum is replaced with circulating inert gas, preferably argon, for convective cooling. After sufficient cooling of the crucible to facilitate subsequent handling, the inert gas is purged with air in preparation for unsealing and lowering the reactor bottom assembly 6. In the preferred embodiment where the crystallization step is omitted, cooling of the crucible 11 and material crust 14 can also be omitted so that energy consumption in subsequent processing steps can be minimized as applicable.
7. A crucible-unloading step is shown in FIG. 10. Preferably, the reactor bottom assembly is unsealed and lowered and the crucible 11 with the crystalline material ingot 17 is unloaded.

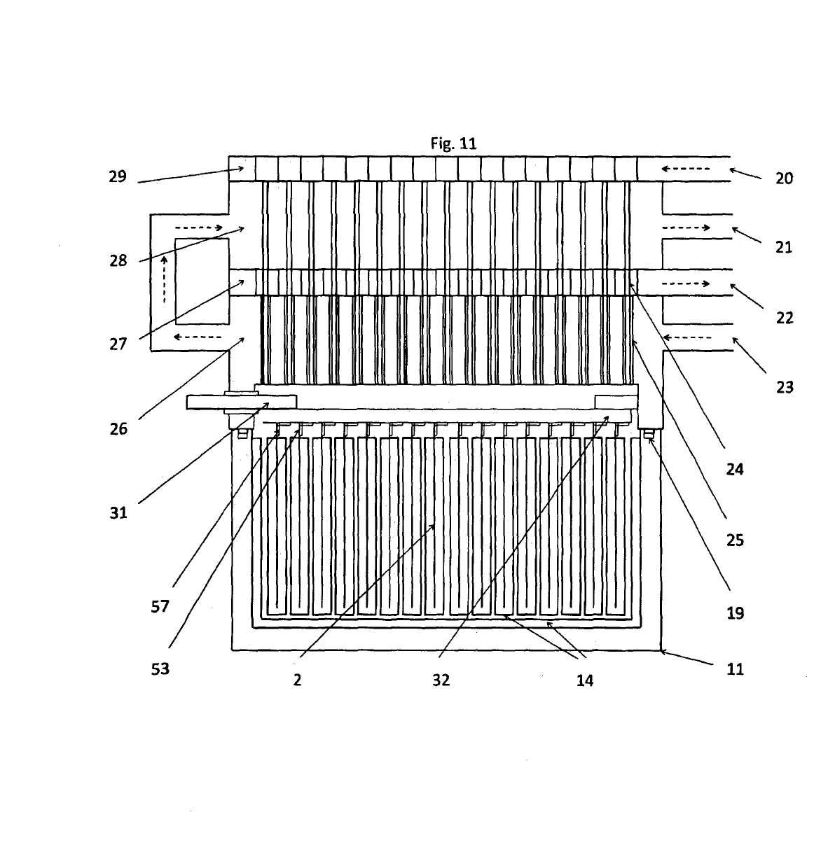

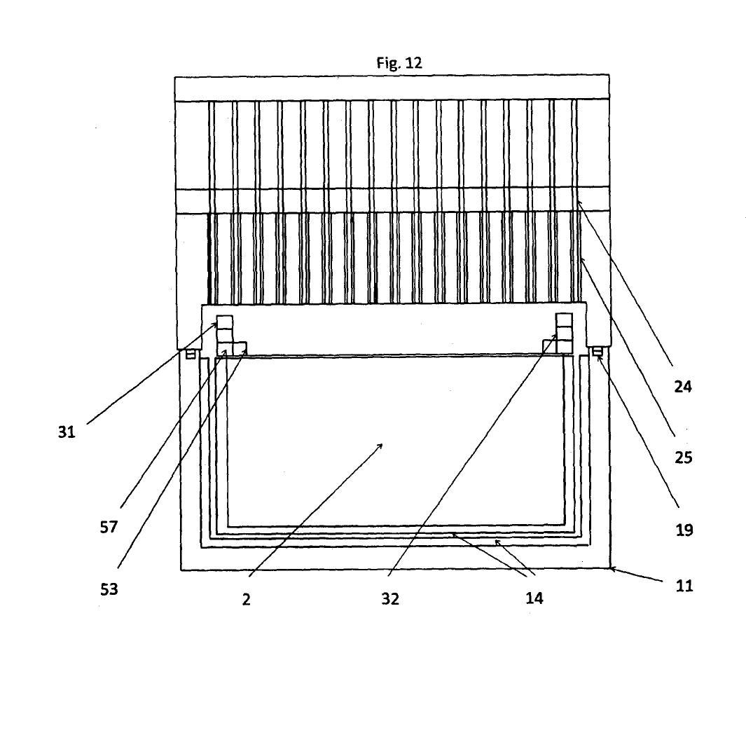

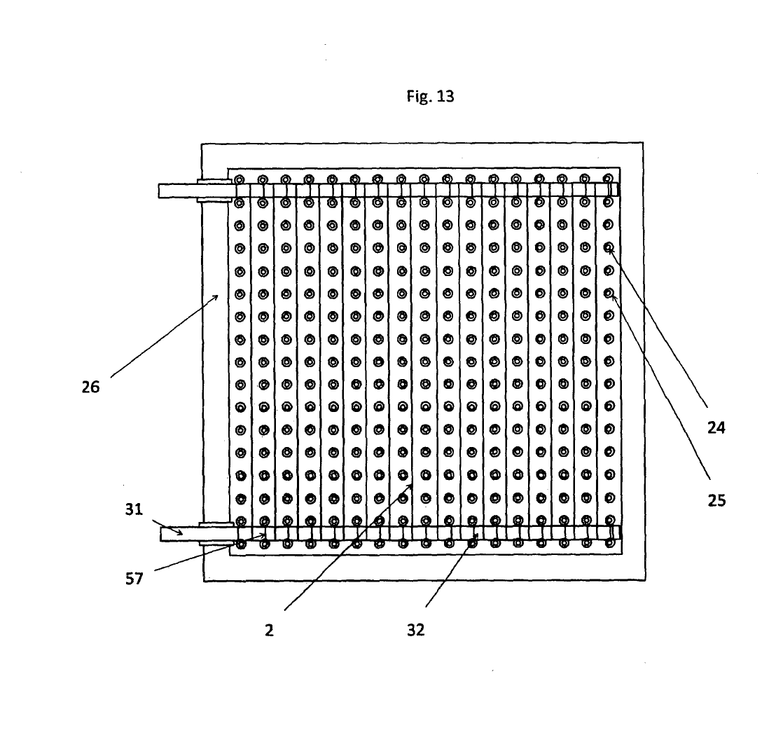

A feature of the preferred embodiment of the cartridge reactor 50 is the effective distribution and preheating of the deposition gas mix that is achieved in the reactor top assembly 1. In FIG. 11, which is a side elevation section of the reactor top assembly 1, the deposition gas mix enters into the deposition gas mix inlet manifold 29 through the deposition gas mix inlet 20. In this preferred embodiment, the deposition gas mix is routed into a multiplicity of deposition gas mix inlet nozzles 24 which extend downward and open at the bottom surface of the reactor top assembly 1 directly above the deposition cartridges 2. The deposition gas mix shoots out through each deposition gas mix nozzle 24, travels downward between the deposition cartridges 2, and strikes the bottom of the crucible 11. The blocking effect of adjacent streams of deposition gas mix striking the bottom of the crucible 11 minimizes the lateral spread of the deposition gas mix and forces it to flow predominantly back up, preferably in a swirling or turbulent motion, between the deposition gas mix exiting the deposition gas mix nozzle 24, preferably in a downward stream, and the deposition cartridges 2 (see also FIGS. 12, 13, and particularly 14). This turbulent flow preferably results in more complete contacting of the deposition gas mix with the deposition cartridges 2 and hence more complete conversion of the material in the deposition gas mix to material on the deposition surfaces.

In this preferred embodiment, the vent gas continues to travel upward where it is removed through a vent gas outlet annulus 25 which surrounds the deposition gas mix inlet nozzle 24 and which is the only escape route. This heated vent gas traveling upward through the vent gas outlet annulus 25 heats the deposition gas mix traveling downward through the deposition gas mix nozzle 24 within. It also heats the cooling water traveling outside of the vent gas outlet annulus in the vent gas aftercooler 26. Other preferred embodiments of the deposition gas mix distribution pattern include individual alternating inlet and outlet nozzles or rows of alternating inlet and outlet nozzles.

The vent gas is collected into a single stream from the multiplicity of vent gas outlet annuli 25 in the vent gas outlet manifold 27 and exits the reactor top assembly through the vent gas outlet 22. Meanwhile, cooling water that has been heated in the vent gas aftercooler 26 flows on to the deposition gas mix preheater 28 where it provides initial heating to the deposition gas mix that has just entered the deposition gas mix inlet nozzles 24. This cooling water then exits the reactor top assembly 1 through the cooling water outlet 21.

FIGS. 11 and 13 show one preferred embodiment of the reactor top assembly 1 with the positioning of the deposition gas mix inlet nozzles 24 directly above the gap between the deposition cartridges 2 which are attached to the distribution bars 32. FIGS. 11 and 13 also show the deposition cartridges 2 electrically connected in parallel via the distribution bars 32, which themselves are is connected to an electrical power supply via the distribution bar electrode 31 which forms an electrically insulated airtight seal against the side wall of the vent gas aftercooler 26. In another preferred configuration, the electrode tabs 53 or electrode brackets 57 can be extended up and out through the top of the reactor top assembly 1 through insulated steel tubes and can be connected to the power supply at a point on top of the reactor top assembly 1.

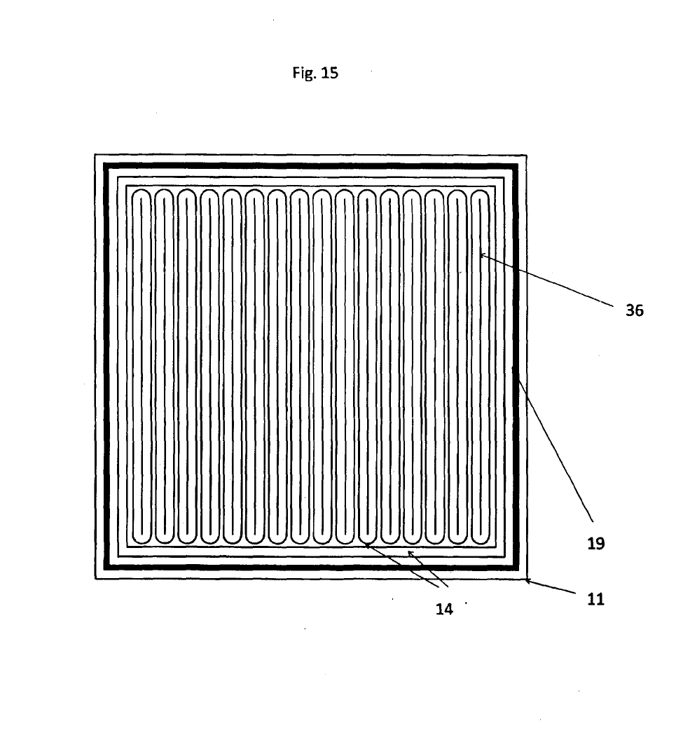

A preferred embodiment of the crucible 11 after deposition and separation from the deposition cartridges 2 is shown in FIG. 15. Material which has deposited onto the inside walls of the crucible 11 and the deposition surfaces of the deposition cartridges 2 fills most of the volume of the crucible and narrow deposition cartridge voids 36 remain in place of the deposition cartridges 2.

The preferred benefits of the cartridge reactor over Siemens reactors are:
1. Faster volumetric deposition rate due to higher surface area for deposition
2. Higher actual conversion rate of material in the deposition gas mix to material on the deposition surfaces resulting from higher ratio of deposition surface area to deposition gas mix containment volume and more complete contacting of deposition gas mix with deposition surfaces made possible by the combination of the deposition cartridge geometry and the gas inlet nozzle geometry
3. Energy savings due to minimized radiant heat loss arising from the deposition cartridge geometry. The majority of radiant heat emitted from heated deposition surfaces is absorbed by adjacent deposition surfaces.
4. Energy savings due to minimized radiant, conductive, and convective heat loss to water-cooled reactor walls. Since deposition occurs inside a sealed crucible, the reactor walls outside the crucible can be blocked by heat shields.
5. Energy savings due to melting, for crystallization, of material from deposition temperature rather than from ambient temperature. Whether crystallization occurs in the cartridge reactor or in separate crystallization equipment, the material is already in the crucible and does not need to be handled directly and therefore does not need to be cooled to ambient temperature.
6. Elimination of contamination of material from handling and elimination of operations for reduction of contamination from handling, such as acid etching
7. Elimination of operations to crush material into manageable-sized chunks for loading into crucibles
8. Faster and higher quality crystallization due to controlled withdrawal of the deposition cartridges from the melted silicon.
9. Plant savings due to more complete conversion of deposition gas mix into vent gas and therefore less vent gas to process downstream of the cartridge reactor
10. Simplified electrical system composed of a single electrode pair for connecting the deposition cartridges in parallel or in series, as compared to an individual electrode pair for each rod pair in a Siemens reactor
11. Increased safety due to flammable deposition gas mix being sealed inside the additional walls of the crucible and inert gas in the reactor cavity being maintained at slightly higher pressure than the deposition gas mix in the crucible
12. Easily scalable design. Simply increasing the plan cross-section of the cartridge reactor to include a higher number of deposition gas mix inlet nozzles and a higher number of longer deposition cartridges, and also increasing the height of the deposition cartridges can significantly increase the production capacity of the cartridge reactor without major reengineering of the rest of the cartridge reactor. Easily scalable directional solidification, which would be a challenge with external heating of the melted material can be achieved through heating and controlled withdrawal of the deposition cartridges from the melted silicon.

What is claimed is:

1. A method for producing materials via the chemical vapor deposition process comprising:
a. Providing a container which can be sealed from the surrounding free space
b. Providing deposition surfaces which can be heated and which can be placed inside the container
c. Providing for the flow of deposition gas mix into the container while avoiding the flow of deposition gas mix in the free space surrounding the container
d. Providing for the flow of vent gas out of the container while avoiding the flow of vent gas in the free space surrounding the container
e. Placing the deposition surfaces inside the container, sealing the container from the surrounding free space, heating the deposition surfaces, flowing deposition gas mix into the container, and flowing vent gas out of the container, such that crusts of material deposit onto the deposition surfaces and substantially fill the void volume of the container
f. Stopping and purging the flow of deposition gas mix into the container and continuing the production cycle in any of the following ways:
i. In the case where the deposition surfaces are made from the same material as the deposited material, simply unsealing the container, and recovering the container substantially filled with the crusts of material for further processing
ii. In the case where the deposition surfaces are made from a material or combination of materials that has a higher melting temperature than the material to be produced and a solid product is desired:
1. Further heating the deposition surfaces to or above the melting temperature of the material such that a thin layer of the material at the deposition surface interfaces liquefies and the crusts of material detach
2. Unsealing the container and separating the heated deposition surfaces from the detached crusts of material in the container
3. Recovering the container substantially filled with the crusts of material for further processing
iii. In the case where the deposition surfaces are made from a material or combination of materials that has a higher melting temperature than the material to be produced and a melted product is desired:
1. Further heating the deposition surfaces to or above the melting temperature of the material, and keeping the deposition surfaces in contact with the material until the material melts
2. Unsealing the container and separating the heated deposition surfaces from the melted material in the container
3. Recovering the container substantially filled with the melted material for further processing
iv. In the case where the deposition surfaces are made from a material or combination of materials that has a higher melting temperature than the material to be produced and a crystalline product is desired:
1. Further heating the deposition surfaces to or above the melting temperature of the material, and keeping the deposition surfaces in contact with the material until the material melts
2. Unsealing the container and separating the heated deposition surfaces from the melted material at a controlled rate such that specific cooling and crystallization of the material occurs
3. Recovering the container substantially filled with the crystallized material for further processing

2. A method and reactor for producing materials via the chemical vapor deposition process comprising:
a. Providing a reactor which can be sealed from the surrounding free space
b. Providing a container which can be placed inside the reactor and which can be sealed from the rest of the free space inside the reactor
c. Providing deposition surfaces which can be heated and which can be placed inside the container
d. Providing for the flow of deposition gas mix from outside of the reactor to inside of the container which is within the reactor while avoiding the flow of deposition gas mix in the rest of the free space inside the reactor
e. Providing for the flow of vent gas from inside of the container which is within the reactor to outside of the reactor while avoiding the flow of vent gas in the rest of the free space inside the reactor
f. Placing the container inside the reactor and sealing the reactor from the surrounding free space
g. Placing the deposition surfaces inside the container and sealing the container from the rest of the free space inside the reactor
h. Heating the deposition surfaces, flowing deposition gas mix into the container, and flowing vent gas out of the container, such that crusts of material deposit onto the deposition surfaces and substantially fill the void volume of the container
i. Stopping and purging the flow of deposition gas mix into the container and continuing the production cycle in any of the following ways:
i. In the case where the deposition surfaces are made of the same material as the deposited material, simply unsealing the container, unsealing the reactor, and recovering the container substantially filled with the crusts of material for further processing
ii. In the case where the deposition surfaces are made from a material or combination of materials that has a higher melting temperature than the material to be produced and a solid product is desired:
1. Further heating the deposition surfaces to or above the melting temperature of the material such that a thin layer of the material at the deposition surface interfaces liquefies and the crusts of material detach
2. Unsealing the container and separating the heated deposition surfaces from the detached crusts of material in the container
3. Unsealing the reactor and recovering the container substantially filled with the crusts of material for further processing
iii. In the case where the deposition surfaces are made from a material or combination of materials that has a higher melting temperature than the material to be produced and a melted product is desired:
1. Further heating the deposition surfaces to or above the melting temperature of the material, and keeping the deposition surfaces in contact with the material until the material melts
2. Unsealing the container and separating the heated deposition surfaces from the melted material in the container
3. Unsealing the reactor and recovering the container substantially filled with the melted material for further processing
iv. In the case where the deposition surfaces are made from a material or combination of materials that has a higher melting temperature than the material to be produced and a crystalline product is desired:
1. Further heating the deposition surfaces to or above the melting temperature of the material such that a thin layer of the material at the deposition surface interfaces liquefies and the crusts of material detach
2. Melting the material in any of the following ways:
a. Melting with the deposition surfaces, by keeping the heated deposition plates in contact with the material until the material melts
b. Melting with a heater that is external to the container but internal to the reactor, comprising:
i. Unsealing the container and separating the heated deposition surfaces from the detached crusts of material in the container
ii. Melting the material in the container with the heater that is external to the container but internal to the reactor
3. Crystallizing the melted material in any of the following ways:
a. Unsealing the container and separating the heated deposition surfaces from the melted material at a controlled rate such that specific cooling and crystallization of the material occurs
b. Providing heating from the heater that is external to the container but internal to the reactor at a controlled rate such that specific cooling and crystallization of the material occurs
c. Providing a cooler that is external to the container but internal to the reactor and proving cooling from this cooler at a controlled rate such that specific cooling and crystallization of the material occurs
d. Providing a rotating puller rod that is dipped into and pulled out of the melted material at a controlled rate such that crystallization of the material occurs
4. Unsealing the reactor and recovering the container substantially filled with the crystallized material for further processing
